(19) United States
(12) Patent Application Publication
(10) Pub. No.: US 2017/0097384 A1
(43) Pub. Date: Apr. 6, 2017

(54) ELECTRIC LEAKAGE DETECTING DEVICE OF IN-VEHICLE POWER SUPPLY SYSTEM AND HYDRAULIC EXCAVATOR

(71) Applicant: Komatsu Ltd., Tokyo (JP)

(72) Inventors: Kentaro Yamada, Hiratsuka-shi (JP); Yasushi Kawaji, Hiratsuka-shi (JP)

(21) Appl. No.: 15/126,482

(22) PCT Filed: Jan. 7, 2015
(86) PCT No.: PCT/JP2015/050289

§ 371 Date: Sep. 15, 2016

(30) Foreign Application Priority Data
Mar. 19, 2014 (JP) 2014-057204

(51) Int. Cl. G01R 31/02; B60L 3/00; E02F 9/12; H02M 7/537; E02F 9/26; H02P 27/06; H02P 6/14; G01R 31/00; E02F 9/20

(52) U.S. Cl. CPC G01R 31/025; G01R 31/007; B60L 3/0061; E02F 9/123; E02F 9/2095; E02F 9/267; H02P 27/06; H02P 6/14; H02M 7/537; B60L 2210/40; E02F 9/2004

(57) ABSTRACT

An electric leakage detecting device of an in-vehicle power supply system includes a detection signal generating unit which applies AC voltage to a voltage applying point on an electric cable connecting a power converting circuit which converts power from a power source to AC power to supply to a motor to the power source; a voltage measuring unit which measures voltage at a voltage measuring point between the detection signal generating unit and the voltage applying point; and an electric leakage detecting unit which detects whether there is electric leakage between the power converting circuit and the motor according to the voltage at the voltage measuring point measured by the voltage measuring unit when a control device of the motor provides an instruction to maintain a rotational angle constant to the motor.

### FIELD

The present invention relates to an electric leakage detecting device of an in-vehicle power supply system which converts DC power of a storage battery to AC power by a power converting circuit and supplies the AC power to an AC motor and a hydraulic excavator.

### BACKGROUND

Recently, a vehicle such as a hybrid vehicle which covers a part of or entire power with power supplied from a storage battery is developed. A power supply system which converts DC power of the storage battery to AC power by using a power converting circuit such as an inverter and supplies the AC power to a load such as an AC motor is mounted on many of such vehicles.

Since a high-voltage and high-capacity storage battery is used in the power supply system, if electric leakage occurs in any site of an electric circuit, this might interfere with maintenance work of the vehicle. Therefore, in an in-vehicle power supply system, it is required to know presence of the electric leakage in advance and to rapidly cope with this if the electric leakage is found.

FIG. 4 is a view illustrating an electric leakage detecting device of the in-vehicle power supply system conventionally used. Such electric leakage detecting device is disclosed in Patent Literatures 1 and 2 below, for example.

In FIG. 4, the electric leakage detecting device of the in-vehicle power supply system is formed of a power supply system 10 and an electric leakage detecting device 20.

The power supply system 10 is formed of a DC high-voltage circuit A and an AC high-voltage circuit B. The DC high-voltage circuit A is formed of a DC storage battery 11, a positive electrode electric cable 13 and a negative electrode electric cable 14 connected to positive and negative electrodes of the storage battery 11, contactors 17a and 17b provided on the positive electrode electric cable 13 and the negative electrode electric cable 14, respectively, and a smoothing capacitor 18 connected to the positive electrode electric cable 13 and the negative electrode electric cable 14 located on a subsequent stage of the contactors 17a and 17b. The AC high-voltage circuit B is formed of an inverter circuit 12 connected to the positive electrode electric cable 13 and the negative electrode electric cable 14 to convert DC power to AC power by switching on/off a plurality of switching devices, an AC motor 15, and a plurality of AC electric cables 16 which connects the inverter circuit 12 to the AC motor 15.

When the AC motor 15 is driven, the contactors 17a and 17b are turned on.

An IGBT inverter circuit 12 illustrated in FIG. 5, for example, is used as the inverter circuit 12. Six IGBT circuits 70 to 75 formed of six IGBT devices (switching devices) 76 and corresponding six diodes 77, respectively, are provided on the IGBT inverter circuit 12.

When the AC motor 15 is a three-phase motor, three groups of IGBT circuits of the IGBT circuits 70 and 73, the IGBT circuits 71 and 74, and the IGBT circuits 72 and 75 are arranged in parallel. An intermediate point M1 between the IGBT circuits 70 and 73, an intermediate point M2 between the IGBT circuits 71 and 74, and an intermediate point M3 between the IGBT circuits 72 and 75 are connected to three coils of the AC motor 15, respectively.

The electric leakage detecting device 20 is formed of a capacitor C connected to a voltage applying point P on the positive electrode electric cable 13 on a positive electrode side of the storage battery 11, a resistance R connected to the capacitor C, an oscillator 21 which oscillates an AC signal Vs of a predetermined frequency such as a sine wave and a rectangular wave to pass the AC signal Vs through the resistance R, and a voltage measuring unit 40 which measures a voltage level (effective value of AC voltage) at a voltage measuring point Q between the resistance R and the capacitor C. When the voltage is measured by the voltage measuring unit 40, a threshold for determining whether there is the electric leakage is set.

An electric leakage detecting process by the electric leakage detecting device 20 in FIG. 4 is performed in the following manner. Suppose a case in which insulation is deteriorated and the electric leakage occurs in the negative electrode electric cable 14. The AC signal Vs output from the oscillator 21 passes through the resistance R and the capacitor C to be applied to the applying point P on the positive electrode electric cable 13.

If there is no electric leakage in the power supply system 10, the voltage effective value measured by the voltage measuring unit 40 is substantially the same as the voltage effective value of the AC signal Vs output from the oscillator 21 and is not lower than the set threshold. According to this, it is determined that there is no electric leakage.

On the other hand, when there is the electric leakage in the power supply system 10, that is to say, when there is the electric leakage on the negative electrode electric cable 14, electric leakage resistance r is generated between the negative electrode electric cable 14 and a body of a vehicle body (ground). Therefore, the voltage effective value of the AC signal Vs is divided by the resistance R and the electric leakage resistance r. Therefore, the voltage effective value measured by the voltage measuring unit 40 becomes smaller than the voltage effective value of the AC signal Vs output from the oscillator 21 to be lower than the set threshold. According to this, it is determined that there is the electric leakage. By measuring the voltage at the measuring point Q to compare with the threshold in this manner, it is possible to detect whether there is the electric leakage. Meanwhile, C represents straying capacitance.

### CITATION LIST

### Patent Literature

Patent Literature 1: WO 2007/007749 A

Patent Literature 2: JP 2003-219551 A

### SUMMARY

### Technical Problem

However, in the conventional electric leakage detecting device, although the electric leakage occurring in the DC high-voltage circuit A out of the power supply system 10 may be detected without risk of erroneous detection, the electric leakage occurring in the AC high-voltage circuit B cannot be detected without the risk of erroneous detection in a state in which high voltage is applied to the high-voltage circuit such as during operation of the vehicle. A reason why the electric leakage cannot be detected in the AC high-voltage circuit B without the risk of erroneous detection in a state in which the high voltage is applied to the high-voltage circuit is hereinafter described with reference to FIGS. 4 and 5. Herein, the capacitor 18 has higher capacitance and smaller impedance in general as compared to those of the capacitor C of the electric leakage detecting device 20. Therefore, the AC signal Vs may pass through the capacitor 18, so that it is described considering that this may pass through both the positive electrode 13 and the negative electrode 14 of a high-voltage section.

Suppose a case in which insulation is deteriorated in any one of the AC electric cables 16a to 16c of the AC high-voltage circuit B and the electric leakage occurs. When on/off control of the IGBT device 76 is stopped in the state in which the high voltage is applied to the high-voltage circuit, each IGBT device 76 is in a non-conductive state. Therefore, the AC signal Vs cannot pass through each IGBT device 76.

Furthermore, when the on/off control of the IGBT device 76 is stopped in the state in which the high voltage is applied to the high-voltage circuit, each diode 77 is put into the non-conductive with the high voltage applied in an opposite bias direction. Therefore, the AC signal Vs cannot pass through each diode 77. Therefore, when the on/off control of the IGBT device 76 is stopped in the state in which the high voltage is applied to the high-voltage circuit, the electric leakage may be detected without the risk of erroneous detection in the DC high-voltage circuit A by the method disclosed in Patent Literature 1, but the electric leakage cannot be detected in the AC high-voltage circuit B.

Next, when the on/off control of the IGBT device 76 is in operation in the state in which the high voltage is applied to the high-voltage circuit, any of the IGBT devices 76 is put into a conductive state. Each diode 77 is put into the conductive state when reflux current flows. Therefore, the AC signal Vs may pass through the AC high-voltage circuit B. However, when the on/off control of the IGBT device 76 is in operation in the state in which the high voltage is applied to the high-voltage circuit, large noise is generated in the electric leakage detecting device 20. This noise includes a plurality of noises with different frequencies and amplitudes. Furthermore, when the impedance in each portion of the high-voltage circuit changes due to change in an insulating state, the amplitude of each noise and the like changes.

Therefore, it is difficult to detect the electric leakage in the AC high-voltage circuit B without the risk of erroneous detection in the state in which the high voltage is applied to the high-voltage circuit such as during the vehicle operation. However, in order to prevent progress of a breakdown when the breakdown occurs, it is required to detect the electric leakage occurring in the AC high-voltage circuit B without the risk of erroneous detection also in the state in which the high voltage is applied to the high-voltage circuit.

The present invention is suggested in consideration of the above-described circumstances and an object thereof is to detect the electric leakage without the risk of erroneous detection with an inexpensive circuit configuration in both the DC high-voltage circuit and AC high-voltage circuit also in the state in which the high voltage is applied to the high-voltage circuit.

### Solution to Problem

According to the present invention, an electric leakage detecting device of an in-vehicle power supply system comprises: a detection signal generating unit which applies AC voltage to a voltage applying point on an electric cable connecting a power converting circuit to a power source, the power converting circuit converting DC power from the power source to AC power to supply to a motor; a voltage measuring unit which measures voltage at a voltage measuring point between the detection signal generating unit and the voltage applying point; and an electric leakage detecting unit which detects whether there is electric leakage between the power converting circuit and the motor according to the voltage at the voltage measuring point measured by the voltage measuring unit when a control device of the motor provides an instruction to maintain a rotational angle within a specific range to the motor.

It is preferable that it comprises: a filter which removes noise of a frequency corresponding to a control cycle when the control device controls to maintain the rotational angle of the motor within the specific range.

### Advantageous Effects of Invention

The present invention may detect the electric leakage without the risk of erroneous detection with the inexpensive circuit configuration in both the DC high-voltage circuit and AC high-voltage circuit also in the state in which the high voltage is applied to the high-voltage circuit.

### BRIEF DESCRIPTION OF DRAWINGS

FIG. 1 is a view illustrating a configuration of an electric leakage detecting device of an in-vehicle power supply system according to an embodiment.

FIG. 2 is a view illustrating a configuration of an electronic control unit as a functional block.

FIG. 3 is a view illustrating the electric leakage detecting device according to the embodiment and a target in which electric leakage is detected by the electric leakage detecting device.

FIG. 4 is a view illustrating an electric leakage detecting device of an in-vehicle power supply system conventionally used.

FIG. 5 is a view illustrating an IGBT inverter circuit.

### DESCRIPTION OF EMBODIMENTS

An embodiment of the present invention is hereinafter described with reference to the drawings.

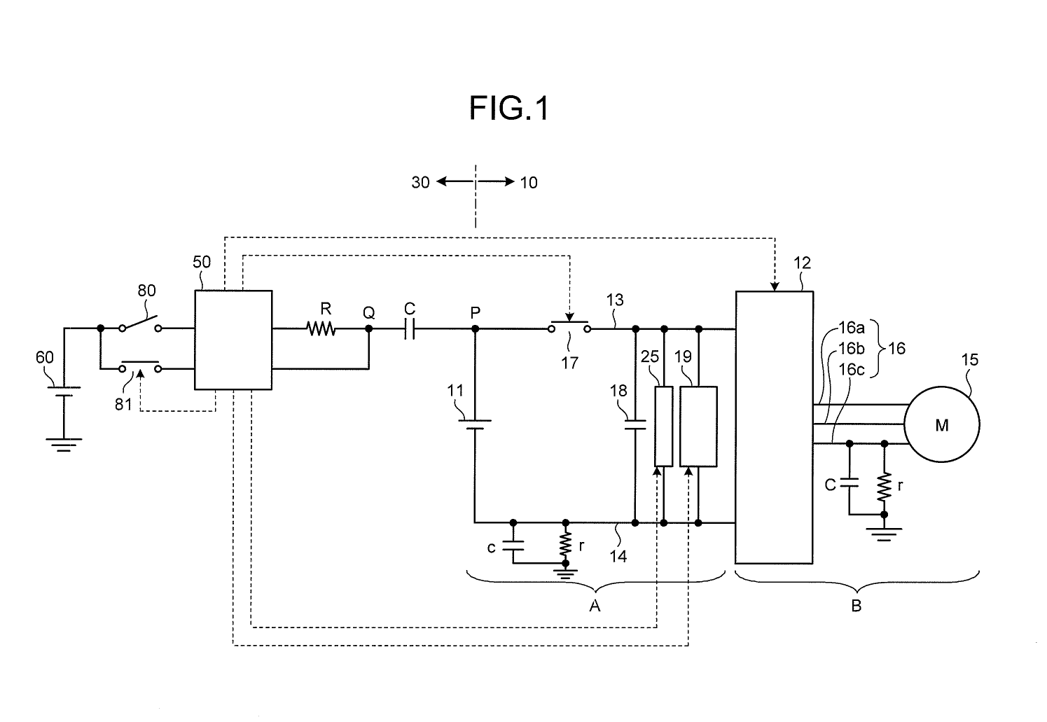

FIG. 1 is a view illustrating a configuration of the embodiment. In FIG. 1, an electric leakage detecting device of an in-vehicle power supply system is formed of a power supply system 10 and an electric leakage detecting device 30.

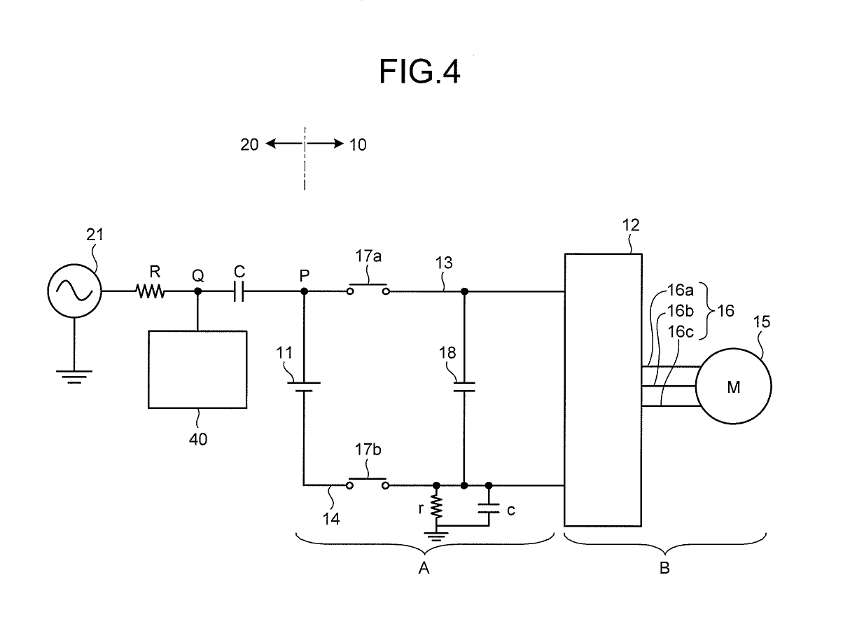

The power supply system 10 illustrated in FIG. 1 is basically the same as a power supply system 10 illustrated in FIG. 4 except that a contactor 17b is not provided on a negative electrode electric cable 14. Although the contactor may be provided on the negative electrode electric cable 14 in this embodiment, it is required that any of the contactors provided on a positive electrode electric cable and the negative electrode electric cable is turned on at the time of an electric leakage detecting process of this embodiment.

The power supply system 10 is formed of a DC high-voltage circuit A and an AC high-voltage circuit B. The DC high-voltage circuit A is formed of a DC storage battery 11, a positive electrode electric cable 13 and the negative electrode electric cable 14 connected to positive and negative electrodes of the storage battery 11, respectively, a contactor 17 provided on the positive electrode electric cable 13, a smoothing capacitor 18 connected to the positive electrode electric cable 13 and the negative electrode electric cable 14 on a subsequent stage of the contactor 17, a DC voltage measuring unit 19 connected in parallel to the capacitor 18, and a voltage extracting circuit 25 connected in parallel to the capacitor 18 to extract DC voltage of the capacitor 18. The voltage extracting circuit 25 is formed of a resistance and a relay, for example.

The AC high-voltage circuit B is formed of an inverter circuit 12 connected to the positive electrode electric cable 13 and the negative electrode electric cable 14 to convert DC power to AC power by switching on/off a plurality of switching devices, an AC motor 15, and a plurality of AC electric cables 16 which connects the inverter circuit 12 to the AC motor 15. The inverter circuit 12 is a power converting circuit which converts the DC power from a power source to the AC power to supply to the AC motor 15 being a motor.

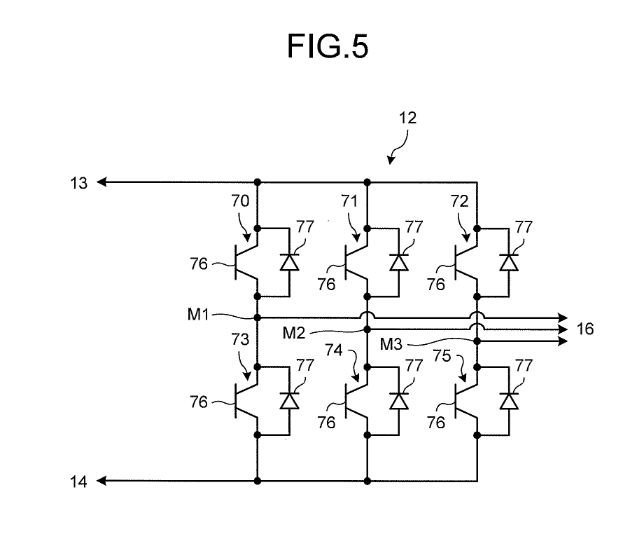

As illustrated in FIG. 5, six IGBT circuits 70 to 75 formed of six IGBT devices 76 and six diodes 77, respectively, are provided on the inverter circuit 12. When the AC motor 15 is a three-phase motor, three groups of the IGBT circuits 70 and 73, the IGBT circuits 71 and 74, and the IGBT circuits 72 and 75 are arranged in parallel.

An intermediate point M1 between the IGBT circuits 70 and 73, an intermediate point M2 between the IGBT circuits 71 and 74, and an intermediate point M3 between the IGBT circuits 72 and 75 are connected to three coils of the AC motor 15, respectively.

The electric leakage detecting device 30 is formed of a capacitor C connected to a voltage applying point P on the positive electrode electric cable 13 on a positive electrode side of the storage battery 11, a resistance R connected to the capacitor C, an electronic control unit 50, a power source 60 of the electronic control unit, a switch 80 which is turned on/off according to operation of a start key of a vehicle to electrically connect/disconnect the electronic control unit 50 to/from the power source 60, and a relay 81 controlled to be turned on/off by the electronic control unit 50 to electrically connect/disconnect the electronic control unit 50 to/from the power source 60.

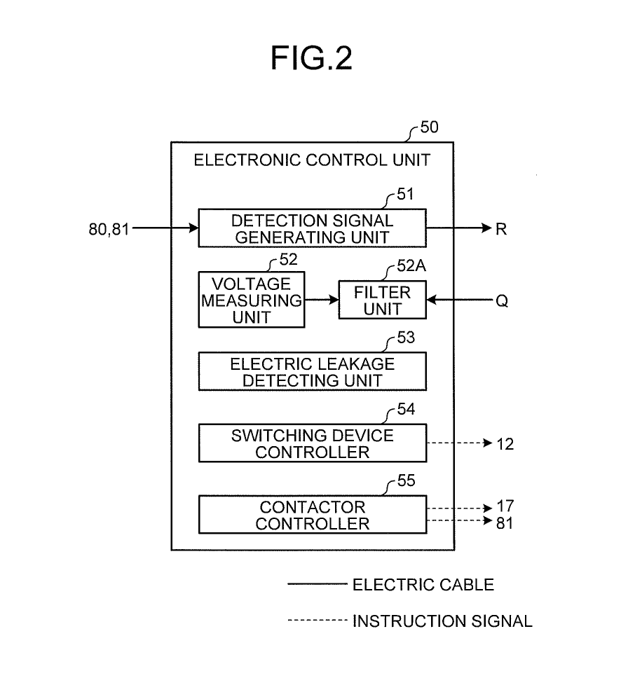

FIG. 2 is a view illustrating a configuration of the electronic control unit 50 as a functional block. The electronic control unit 50 is formed of a detection signal generating unit 51 which oscillates an AC signal Vs of a predetermined frequency such as a sine wave and a rectangular wave pass the AC signal Vs through the resistance R, a voltage measuring unit 52 which measures a voltage level (effective value of AC voltage) at a voltage measuring point Q between the resistance R and the capacitor C through a filter unit 52A, an electric leakage detecting unit 53 which detects whether there is electric leakage by comparing the voltage measured by the voltage measuring unit 52 with a threshold set in advance, a switching device controller 54 which controls to turn on/off each IGBT device (switching device) 76 provided on the IGBT inverter circuit 12, and a contactor controller 55 which controls to turn on/off the contactor 17 and the relay 81. A function of each of the units 51 to 55 of the electronic control unit 50 is realized by an electronic circuit or programming.

Meanwhile, although the contactor 17 is provided on the positive electrode electric cable 13 in this embodiment, this may also be provided on the negative electrode electric cable 14. Although the voltage applying point P to which the AC voltage Vs is applied is provided on the positive electrode electric cable 13 in this embodiment, it is also possible to provide the voltage applying point P on the negative electrode electric cable 14.

A reason why large noise is generated in the electric leakage detecting device 30 when on/off control of the IGBT device 76 is in operation in a state in which high voltage is applied to the high-voltage circuit and a solution thereto are described with reference to FIGS. 1 and 5.

When the on/off control of the IGBT device 76 is in operation in the state in which the high voltage is applied to the high-voltage circuit, large voltage fluctuation occurs at M1 to M3 of the AC high-voltage circuit B. Voltage obtained by dividing the voltage fluctuation by impedance of insulating resistance r and straying capacitance c and impedance of the resistance R and the capacitor C of the electric leakage detecting device 30 is generated as the noise in the electric leakage detecting device 30.

Herein, the voltage fluctuation at M1 to M3 of the AC high-voltage circuit B mainly occurs by switching of each IGBT device 76. The voltage fluctuation mainly includes a component of a carrier frequency (switching frequency) and a component of a frequency in which a time ratio between the positive electrode voltage and the negative electrode voltage changes, that is to say, a phase current frequency.

Herein, as for the voltage fluctuation of the carrier frequency, since a designer may arbitrarily determine a control cycle of the carrier frequency, the designer may arbitrarily determine both the noise frequency and the frequency of the AC signal Vs. Therefore, protection against the noise may be surely performed by a filter and the like.

However, as for the voltage fluctuation of the phase current frequency, the frequency changes in proportional to a motor speed. Therefore, when the AC motor 15 is used for vehicle travel and swing, the designer cannot arbitrarily determine the noise frequency.

Furthermore, although it is necessary to secure sufficient detection time for surely detecting the electric leakage, it is not always true that the motor speed at which the protection against the noise may be performed is sufficiently continued immediately after the electric leakage occurs.

For this, the electric leakage detecting device of the present invention takes following measures for the protection against the noise of the phase current frequency described above.

In the AC motor 15 used for the vehicle travel and the swing of a hybrid hydraulic excavator and an electric excavator, an instruction to maintain a rotational angle within a specific range is provided from a control device of the AC motor 15 before and after stopping motor rotation and applying a mechanical brake.

While the rotational angle is maintained within the specific range, the noise of a wide frequency band synchronized with the phase current frequency disappears to be replaced with the noise of a constant frequency synchronized with the control cycle of the control instruction of the rotational angle.

In the present invention, focusing on this phenomenon, the electric leakage in the AC high-voltage circuit B in the state in which the high voltage is applied is detected during the period in which the rotational angle is maintained within the specific range.

Herein, since the designer may arbitrarily determine the control cycle of the control instruction of the rotational angle, the designer may arbitrarily set both the noise frequency and the AC signal Vs. Therefore, the protection against the noise may be surely performed by the filter unit 52A.

Furthermore, the designer may also arbitrarily determine a time period during which the instruction to maintain the rotational angle within the specific range is continued, so that it becomes possible to surely secure the sufficient detection time.

By taking the above-described measures, it becomes possible to surely perform stable electric leakage detection in each cycle of rotation and stop of the AC motor 15 also in the state in which the high voltage is applied to the high-voltage circuit.

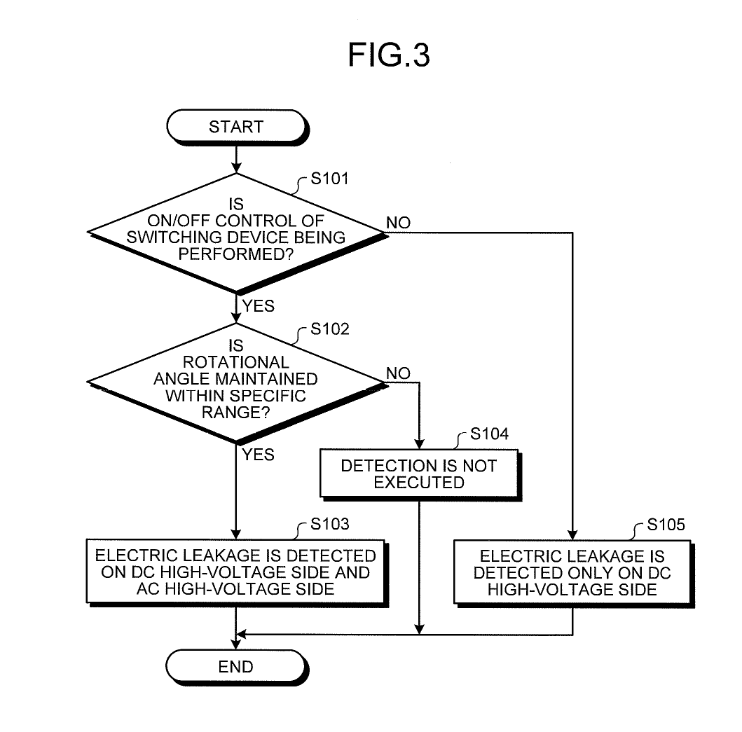

Next, a procedure of the electric leakage detection of this embodiment is described with reference to FIG. 3. When the electric leakage detection is performed during operation of the vehicle, the procedure is branched according to whether the on/off control of the IGBT device 76 is stopped or not. A state of the on/off control of the IGBT device 76 may be easily determined because a CPU itself is in charge of the control instruction.

When the on/off control of the IGBT device 76 is stopped (step S101; No), as described above, the electric leakage is detected only on a DC high-voltage side at step S105. When the on/off control of the IGBT device 76 is in operation (step S101; Yes), the procedure is branched according to whether the instruction to maintain the rotational angle of the AC motor 15 within the specific range is output at step S102. This may also be easily determined because the CPU itself is in charge of the control instruction.

When the instruction to maintain the rotational angle within the specific range is output (step S102; Yes), the electric leakage is detected on both the DC high-voltage side and an AC high-voltage side as described above at step S103. When the instruction to maintain the rotational angle within the specific range is not output (step S102; No), the electric leakage detection is not executed at step S104.

Meanwhile, also in a case in which the instruction to maintain the rotational angle within the specific range is not output, when a specific condition that a state in which the motor speed is not lower than a threshold continues for a certain time period or longer, for example, is satisfied, the electric leakage detection may be performed similarly.

Furthermore, in a case in which the electric leakage is detected while the on/off control of the IGBT device 76 is in operation, it is also possible to diagnose in which of the DC high-voltage circuit A and the AC high-voltage circuit B the electric leakage occurs by stopping the on/off control of the IGBT device 76 while applying the high voltage to the high-voltage circuit and detecting whether there is the electric leakage again while stopping the on/off control. That is to say, in a state in which the on/off control is stopped, when it is determined that there is no electric leakage, it is understood that the electric leakage occurs in the AC high-voltage circuit B. On the other hand, when it is determined that there is the electric leakage also in the state in which the on/off control is stopped, it is understood that the electric leakage occurs in the DC high-voltage circuit A.

According to this embodiment, it is possible to detect whether there is the electric leakage not only in the DC high-voltage circuit A but also in the AC high-voltage circuit B also during the vehicle operation. According to this, it becomes possible to detect the occurrence of the electric leakage early to prevent progress of a breakdown.

Furthermore, according to this embodiment, it is possible to specify in which of the DC high-voltage circuit A and the AC high-voltage circuit B the electric leakage occurs. Therefore, an electric leakage site may be rapidly repaired and work efficiency is improved.

A specific method of detecting the electric leakage is hereinafter described. When the electric leakage (electric leakage resistance r) does not occur in the high-voltage circuit, the voltage effective value at the voltage measuring point Q measured by the voltage measuring unit 52 is substantially the same as the voltage effective value of the AC signal Vs output from the detection signal generating unit 51 and the electric leakage detecting unit 53 determines that the measured voltage is not lower than the set threshold. According to this, it is determined that there is no electric leakage.

On the other hand, when there is the electric leakage in the high-voltage circuit, for example, when there is the electric leakage (electric leakage resistance r) on the negative electrode electric cable 14, the voltage effective value of the AC signal Vs is divided by the resistance R and the electric leakage resistance r. Therefore, the voltage effective value measured by the voltage measuring unit 52 becomes smaller than the voltage effective value of the AC signal Vs output from the detection signal generating unit 51 and the electric leakage detecting unit 53 determines that the measured voltage is lower than the set threshold. According to this, it is determined that there is the electric leakage.

When the electric leakage is detected, required measures such as vehicle stop is performed. It is also possible to display on a display device not illustrated whether there is the electric leakage and the electric leakage site. According to this, a worker may rapidly repair the electric leakage site.

In addition, specific noise and filter are hereinafter described. In order to detect the electric leakage in the AC high-voltage circuit B, the electric leakage detecting device is required to detect the electric leakage in a state in which the detection signal Vs flows toward the AC motor 15, that is to say, during operation of the motor. Herein, during the operation of the motor, the voltage fluctuation due to turning on/off of the switching device for driving the motor is divided at an impedance ratio between a section between a voltage fluctuating portion and ground and a section between an electric leakage detecting circuit and ground, so that the large noise is generated at the voltage measuring point Q. At that time, the capacitor C of the electric leakage detecting circuit removes a DC component, so that only an AC component, that is to say, the voltage fluctuation becomes the noise.

Herein, the noise includes a component widely changes depending on the motor speed. When the impedance in each part of the vehicle changes due to insulation deterioration, the noise also widely changes according to the change of the impedance. As a result, when the electric leakage detecting device detects the electric leakage during the operation of the motor in the state in which the high voltage is applied to the high-voltage circuit, a large-scale circuit for the protection against the noise and complicated logic for detecting the electric leakage are required. Furthermore, there are an enormous number of combinations of operating conditions of the motor and insulation deterioration states, so that a large-scale test is required for operation check.

Herein, as for the rotational angle of the motor, the instruction to maintain the rotational angle within the specific range is provided before and after the motor rotation is stopped and the mechanical brake is applied. At that time, all the noise frequencies reach values determined by the designer as described above and it becomes possible to surely perform the protection against the noise by a small-scale circuit and simple logic.

When the rotational angle of the motor is maintained within the specific range such as immediately before the mechanical brake is applied, the noise derived from the motor is mainly the noise proportional to the frequency to turn on/off the switching device and the frequency of the control instruction of the rotational angle. At that time, the frequency of the AC signal Vs and the frequency of the noise derived from the motor may be determined by the designer, so that the protection against the noise is surely performed by the filter unit 52A.

For example, when the noise depending on the frequency of the on/off control of the switching device is 10 kHz and the noise depending on the control frequency of the rotational angle of the motor is 100 Hz, by setting the AC signal Vs to 5 Hz and removing the noise of the frequency of 50 Hz or higher by a low-pass filter as the filter unit 52A, the protection against the noise may be surely performed. Meanwhile, the noise is generated by division of the voltage fluctuation of the high-voltage circuit, so that wave height of the noise is not higher than the voltage applied to the high-voltage circuit and it is possible to obtain a degree required for the low-pass filter in consideration of this.

A high improvement effect may be obtained by the above-described method especially in the hybrid hydraulic excavator and the electric excavator in which the motor is used in swing work. The hybrid hydraulic excavator is such that a swing motor is driven according to operation of a swing operation lever being an operating device and an upper swing body swings. As the swing motor, the one which independently allows the upper swing body to swing or the one connected to a hydraulic motor to allow the upper swing body to swing by using hydraulic pressure and electric power may be used.

The hybrid hydraulic excavator does not continuously use the swing motor for a long time in general and this repeats short-time swing and stop of the upper swing body during operation. When the swing operation lever is returned to a neutral position and the swing is stopped, a swing parking brake being the mechanical brake is applied; the above-described instruction to maintain the rotational angle within the specific range is output during few seconds before and after the application of the swing parking brake is started. It becomes possible to allow the vehicle to operate immediately after it is checked that there is no electric leakage when the electric leakage is detected at timing at which the instruction to maintain the rotational angle within the specific range is provided. It is possible to surely perform the electric leakage detection each time the swing motor is used. As a result, the high improvement effect may be obtained by the present invention in the hybrid hydraulic excavator. Meanwhile, although the example of performing the electric leakage detection in few seconds before and after starting the application of the swing parking brake is described, the electric leakage may be detected in a predetermined period after the swing operation lever is returned to the neutral position, in a predetermined period before the application of the brake is started, or in a predetermined period including start of the brake application.

### REFERENCE SIGNS LIST

10 POWER SUPPLY SYSTEM

11 STORAGE BATTERY

12 INVERTER CIRCUIT

15 AC MOTOR

16 AC ELECTRIC CABLE

17 CONTACTOR

18 CAPACITOR

19 DC VOLTAGE MEASURING UNIT

20 ELECTRIC LEAKAGE DETECTING DEVICE

21 OSCILLATOR

25 CIRCUIT

30 ELECTRIC LEAKAGE DETECTING DEVICE

40 VOLTAGE MEASURING UNIT

50 ELECTRONIC CONTROL UNIT

51 DETECTION SIGNAL GENERATING UNIT

52 VOLTAGE MEASURING UNIT

52A FILTER UNIT

53 ELECTRIC LEAKAGE DETECTING UNIT

54 SWITCHING DEVICE CONTROLLER

55 CONTACTOR CONTROLLER

1. An electric leakage detecting device of an in-vehicle power supply system comprising:
a detection signal generating unit which applies AC voltage to a voltage applying point on an electric cable connecting a power converting circuit to a power source, the power converting circuit converting DC power from the power source to AC power to supply to a motor;
a voltage measuring unit which measures voltage at a voltage measuring point between the detection signal generating unit and the voltage applying point; and
an electric leakage detecting unit which detects whether there is electric leakage between the power converting circuit and the motor according to the voltage at the voltage measuring point measured by the voltage measuring unit when a control device of the motor provides an instruction to maintain a rotational angle within a specific range to the motor.

2. The electric leakage detecting device of the in-vehicle power supply system according to claim 1, comprising: a filter which removes noise of a frequency corresponding to a control cycle when the control device controls to maintain the rotational angle of the motor within the specific range.

3. The electric leakage detecting device of the in-vehicle power supply system according to claim 1, wherein when the electric leakage is detected, while high voltage is applied, after on/off control of a switching device included in the power converting circuit is stopped, whether there is the electric leakage is detected while the on/off control is stopped.

4. A hydraulic excavator comprising:
a motor which swings an upper swing body;
a power converting circuit which converts DC power from a power source to AC power to supply to the motor; and
the electric leakage detecting device of the in-vehicle power supply system according to claim 1.

5. The hydraulic excavator according to claim 4, further comprising:
a swing operation lever which operates swing movement, wherein
the electric leakage detecting unit detects whether there is electric leakage within a predetermined period after the swing operation lever is returned to a neutral position.
